(19) United States
(12) Patent Application Publication
(10) Pub. No.: US 2025/0169303 A1
(43) Pub. Date: May 22, 2025

(54) DISPLAY APPARATUS AND METHOD OF MANUFACTURING THE SAME

(71) Applicant: SAMSUNG DISPLAY CO., LTD., YONGIN-SI (KR)

(72) Inventors: Sangwook LEE, YONGIN-SI (KR); Inseok LIM, YONGIN-SI (KR); Yeoungkeol WOO, YONGIN-SI (KR); Hyunmin CHO, YONGIN-SI (KR)

(21) Appl. No.: 18/907,729

(22) Filed: Oct. 7, 2024

(30) Foreign Application Priority Data
Oct. 5, 2023 (KR) 10-2023-0132463

(51) Int. Cl. H10K 59/131; H10D 18/60; H10D 86/40; H10K 59/12; H10K 59/121; H10K 71/60

(52) U.S. Cl. CPC H10K 59/131; H10K 59/1201; H10K 59/1213; H10K 59/1216; H10K 71/60; H10D 18/60; H10D 86/421; H10D 86/441

(57) ABSTRACT

A display apparatus may include a first inorganic insulating layer disposed between a first semiconductor layer and a first gate electrode, a second inorganic insulating layer disposed between the first gate electrode and a capacitor electrode, a third inorganic insulating layer disposed on the capacitor electrode, a fourth inorganic insulating layer disposed between a second semiconductor layer and a second gate electrode, a fifth inorganic insulating layer disposed on the second gate electrode, a 1st-1 connection electrode disposed over the fifth inorganic insulating layer and electrically connected to the first semiconductor layer through a 1st-1 contact hole passing through the first to the fifth inorganic insulating layer, and a 1st-1 bridge contact layer covering a portion of the fifth inorganic insulating layer, an inner surface of the 1st-1 contact hole, and a portion of the first semiconductor layer corresponding to the 1st-1 contact hole.

### CROSS-REFERENCE TO RELATED APPLICATION

This application claims priority under 35 U.S.C. § 119 to Korean Patent Application No. 10-2023-0132463, filed on Oct. 5, 2023 in the Korean Intellectual Property Office, the disclosure of which is incorporated by reference in its entirety herein.

### 1. TECHNICAL FIELD

One or more embodiments relate to a display apparatus and a method of manufacturing the display apparatus, and more particularly, to a display apparatus having a reduced defect occurrence possibility during a manufacturing process and a method of manufacturing the display apparatus.

### 2. DISCUSSION OF RELATED ART

A display apparatus includes a display element and a pixel circuit. The pixel circuit is electrically connected to the display element. The pixel circuit includes at least one thin-film transistor. The thin-film transistor includes a semiconductor layer, a gate electrode, a source electrode, and a drain electrode. The source electrode and/or the drain electrode are/is disposed over the semiconductor layer and electrically connected to the semiconductor layer through a contact hole.

However, a defect may occur during the manufacturing of the display apparatus. For example, in a display apparatus according to the related art, a contact hole may have a long shape in a thickness direction and a source electrode and/or a drain electrode are/is disconnected inside the contact hole. Thus, the source electrode and/or the drain electrode are/is not electrically connected to a semiconductor layer.

### SUMMARY

One or more embodiments include a display apparatus with a reduced defect occurrence possibility during a manufacturing process and a method of manufacturing the display apparatus. However, such a technical objective is just an example, and embodiments of the present disclosure are not limited thereto.

Additional aspects will be set forth in part in the description which follows and, in part, will be apparent from the description, or may be learned by practice of the presented embodiments of the disclosure.

According to an embodiment of the present disclosure, a display apparatus includes a first semiconductor layer disposed on a substrate. A first gate electrode is disposed over the first semiconductor layer. A first inorganic insulating layer is disposed between the first semiconductor layer and the first gate electrode. A capacitor electrode is disposed over the first gate electrode to overlap the first gate electrode. A second inorganic insulating layer is disposed between the first gate electrode and the capacitor electrode. A third inorganic insulating layer is disposed on the capacitor electrode. A second semiconductor layer is disposed on the third inorganic insulating layer. A second gate electrode is disposed over the second semiconductor layer. A fourth inorganic insulating layer is disposed between the second semiconductor layer and the second gate electrode. A fifth inorganic insulating layer is disposed on the second gate electrode. A 1st-1 connection electrode is disposed over the fifth inorganic insulating layer. The 1st-1 connection electrode is electrically connected to the first semiconductor layer through a 1st-1 contact hole passing through the first inorganic insulating layer, the second inorganic insulating layer, the third inorganic insulating layer, the fourth inorganic insulating layer, and the fifth inorganic insulating layer. A 1st-1 bridge contact layer covers a portion of the fifth inorganic insulating layer, an inner surface of the 1st-1 contact hole, and a portion of the first semiconductor layer corresponding to the 1st-1 contact hole.

In an embodiment, the 1st-1 bridge contact layer may directly contact the portion of the first semiconductor layer corresponding to the 1st-1 contact hole.

In an embodiment, the 1st-1 connection electrode may directly contact the 1st-1 bridge contact layer.

In an embodiment, the 1st-1 bridge contact layer conformally covers the 1st-1 connection electrode.

In an embodiment, the 1st-1 bridge contact layer may have a shape corresponding to a lower surface of the 1st-1 connection electrode.

In an embodiment, the first semiconductor layer may include a silicon semiconductor.

In an embodiment, the second semiconductor layer may include an oxide semiconductor.

In an embodiment, the 1st-1 bridge contact layer may include amorphous silicon doped with N-type impurities or P-type impurities.

In an embodiment, the 1st-1 bridge contact layer may include tungsten or titanium nitride.

In an embodiment, the display apparatus may further include a 2nd-1 connection electrode disposed over the fifth inorganic insulating layer. The 2nd-1 connection electrode is electrically connected to the second semiconductor layer through a 2nd-1 contact hole passing through the fourth inorganic insulating layer and the fifth inorganic insulating layer. A 2nd-1 bridge contact layer covers a portion of the fifth inorganic insulating layer. The 2nd-1 bridge contact layer is spaced apart from the second semiconductor layer.

In an embodiment, the 2nd-1 connection electrode may directly contact the second semiconductor layer.

In an embodiment, the 2nd-1 bridge contact layer may not directly contact an inner surface of the 2nd-1 contact hole and a portion of the second semiconductor layer corresponding to the 2nd-1 contact hole.

In an embodiment, the 2nd-1 bridge contact layer may include a same material as the 1st-1 bridge contact layer.

According to an embodiment of the present disclosure, a method of manufacturing a display apparatus includes forming a first inorganic insulating layer, a second inorganic insulating layer, a third inorganic insulating layer, a fourth inorganic insulating layer, and a fifth inorganic insulating layer over a substrate, forming a 1st-1 contact hole passing through the first inorganic insulating layer, the second inorganic insulating layer, the third inorganic insulating layer, the fourth inorganic insulating layer, and the fifth inorganic insulating layer, forming a first preliminary bridge contact layer on the fifth inorganic insulating layer, forming a second preliminary bridge contact layer by forming a 2nd-1 contact hole passing through the fourth inorganic insulating layer and the fifth inorganic insulating layer, and removing a portion of the first preliminary bridge contact layer corresponding to the 2nd-1 contact hole, forming a preliminary connection electrode on the second preliminary bridge contact layer, and forming a 1st-1 connection electrode, a 2nd-1 connection electrode, a 1st-1 bridge contact layer, and a 2nd-1 bridge contact layer by patterning the preliminary connection electrode layer and the second preliminary bridge contact layer.

In an embodiment, the forming of the first preliminary bridge contact layer may include forming the first preliminary bridge contact layer using chemical vapor deposition.

In an embodiment, the first preliminary bridge contact layer may include amorphous silicon doped with N-type impurities or P-type impurities.

In an embodiment, the first preliminary bridge contact layer may include tungsten or titanium nitride.

In an embodiment, the forming of the first preliminary bridge contact layer may include covering an inner surface of the 1st-1 contact hole with the first preliminary bridge contact layer.

In an embodiment, the forming of the first inorganic insulating layer, the second inorganic insulating layer, the third inorganic insulating layer, the fourth inorganic insulating layer, and the fifth inorganic insulating layer over the substrate may include forming the first inorganic insulating layer to be disposed between a first semiconductor layer and a first gate electrode, forming the second inorganic insulating layer to be disposed between the first gate electrode and a capacitor electrode, forming the third inorganic insulating layer on the capacitor electrode, forming the fourth inorganic insulating layer to be disposed between a second semiconductor layer and a second gate electrode, and forming the fifth inorganic insulating layer on the second gate electrode.

In an embodiment, the 1st-1 connection electrode may be electrically connected to the first semiconductor layer through the 1st-1 contact hole, and the 2nd-1 connection electrode may be electrically connected to the second semiconductor layer through the 2nd-1 contact hole.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is an equivalent circuit diagram of a pixel of a display apparatus according to an embodiment;

FIG. 3 is a schematic cross-sectional view of a display apparatus of FIG. 1, taken along line I-I′ of FIG. 1 according to an embodiment; and

FIGS. 4 to 9 are schematic cross-sectional views showing some of a process of manufacturing the display apparatus of FIG. 3 according to embodiments of the present disclosure.

### DETAILED DESCRIPTION OF EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the present disclosure, and methods for achieving them will be clarified with reference to embodiments described below in detail with reference to the drawings. However, embodiments of the present disclosure are not limited to the following described embodiments and may be embodied in various forms.

While such terms as “first” and “second” may be used to describe various components, such components are not limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

In the present specification, “A and/or B” means A or B, or A and B. In the present specification, “at least one of A and B” means A or B, or A and B.

In the present specification, when various elements such as a layer, a region, a plate, and the like are disposed “on” another element, not only the elements may be disposed “directly on” the other element, but another element may be disposed therebetween. When various elements such as a layer, a region, a plate, and the like are disposed “directly on” another element, no intervening elements may be disposed therebetween.

It will be understood that when a layer, region, or component is referred to as being “connected” to another layer, region, or component, it may be “directly connected” to the other layer, region, or component or may be “indirectly connected” to the other layer, region, or component with other layer, region, or component therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element therebetween. When a layer, region, or component is referred to as being “directly connected” to another layer, region, or component, no intervening elements may be present.

The x-axis, the y-axis and the z-axis are not necessarily limited to three axes of the rectangular coordinate system, and may be interpreted in a broader sense. For example, the x-axis, the y-axis, and the z-axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially and performed in the opposite order.

In the present specification, “in a plan view” means when an object part is viewed from above. For example, in the present specification, “in a plan view” means when viewed in a direction perpendicular to a substrate 100.

In the present specification, “an upper surface” means a surface in a +z direction, and “a lower surface” means a surface in a −z direction.

In the present specification, “conductivity” means electrical conductivity, “a conductive material” means a material having conductivity, and “for a material or layer to be conductive” means that the material or layer is electrically conductive.

Hereinafter, embodiments will be described with reference to the accompanying drawings, wherein like reference numerals refer to like elements throughout and a repeated description thereof may be omitted. Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

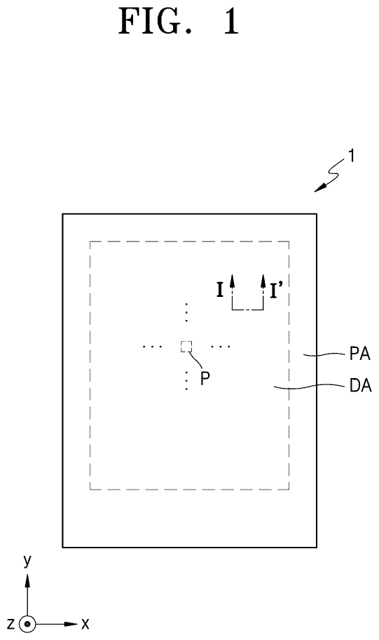

FIG. 1 is a schematic plan view of a display apparatus 1 according to an embodiment. As shown in FIG. 1, the display apparatus 1 may include a display area DA and a peripheral area PA. A plurality of pixels P are arranged in the display area DA. The peripheral area PA is outside the display area DA (e.g., in the X-axis and Y-axis directions). For example, the peripheral area PA may surround the display area DA entirely (e.g., in the X-axis and Y-axis directions).

Each pixel P of the display apparatus 1 is a region configured to emit light of a preset color. The display apparatus 1 may be configured to display images using light emitted from the pixels P. As an example, in an embodiment each pixel P may be configured to emit red, green, or blue light. However, embodiments of the present disclosure are not necessarily limited thereto.

As shown in FIG. 1, the display area DA may have a polygonal shape including a quadrangular shape. As an example, in an embodiment the display area DA may have a rectangular shape in which a horizontal length thereof is less than a vertical length, a rectangular shape in which a horizontal length thereof is greater than a vertical length, or a square shape. Alternatively, the display area DA may have various shapes such as an elliptical shape or a circular shape.

The peripheral area PA may be a non-display area in which the pixels are not arranged. A driver and the like configured to provide electric signals or power to the pixels PX may be arranged in the peripheral area PA. In an embodiment, a plurality of pads may be arranged in the peripheral area PA. The pads are a region to which electronic elements or a printed circuit board may be electrically connected. The pads may be spaced apart from each other in the peripheral area PA and may be electrically connected to a printed circuit board or an integrated circuit element.

Hereinafter, though an organic light-emitting display apparatus is described as an example of the display apparatus 1 according to an embodiment, the display apparatus is not necessarily limited thereto. For example, in an embodiment, the display apparatus 1 may be an inorganic light-emitting display apparatus or a quantum-dot light-emitting display apparatus. As an example, an emission layer of a display element of the display apparatus 1 may include an organic material or an inorganic material. In addition, the display apparatus 1 may include an emission layer and a quantum-dot layer disposed on a path of light emitted from the emission layer.

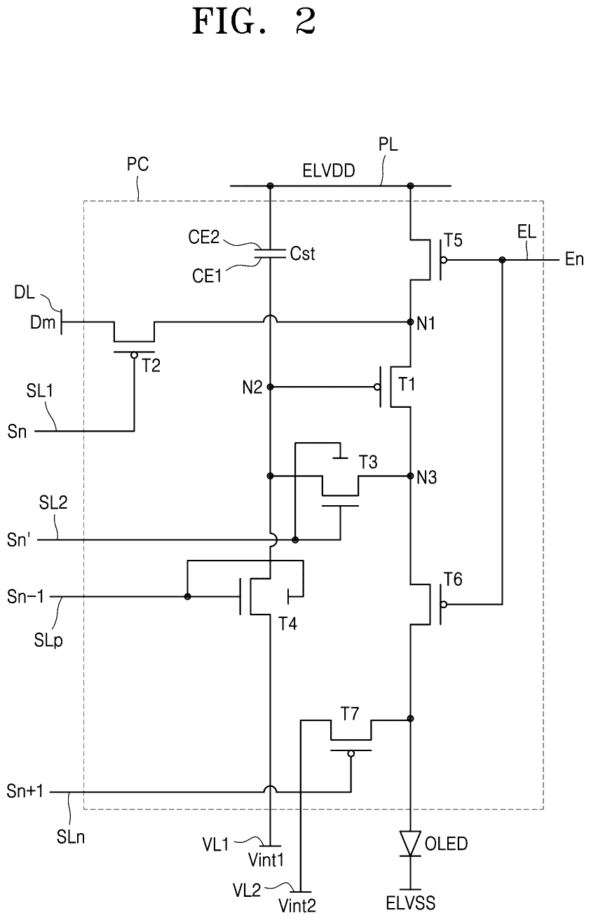

FIG. 2 is an equivalent circuit diagram of a pixel P of the display apparatus 1 according to an embodiment. As shown in FIG. 2, a pixel P may correspond to a display element, and the display element may be electrically connected to a pixel circuit PC. FIG. 2 shows an organic light-emitting diode OLED as a display element. However, embodiments of the present disclosure are not necessarily limited thereto.

As shown in FIG. 2, in an embodiment the pixel circuit PC may include a plurality of thin-film transistors T1, T2, T3, T4, T5, T6, and T7, and a storage capacitor Cst. The plurality of thin-film transistors T1, T2, T3, T4, T5, T6, and T7, and the storage capacitor Cst may be connected to a plurality of signal lines SL1, SL2, SLn, EL, and DL, a first initialization voltage line VL1, a second initialization voltage line VL2, and a driving voltage line PL. At least one of the lines, for example, the driving voltage line PL may be shared by adjacent pixels P.

In an embodiment, the plurality of thin-film transistors T1, T2, T3, T4, T5, T6, and T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a first electrode (e.g., a pixel electrode) and a second electrode (e.g., an opposite electrode). The first electrode of the organic light-emitting diode OLED may be connected to the driving transistor T1 through the emission control transistor T6 to receive a driving current, and the second electrode may receive a common voltage ELVSS. The organic light-emitting diode OLED may be configured to generate light of brightness corresponding to the driving current.

In an embodiment, some of the plurality of thin-film transistors T1, T2, T3, T4, T5, T6, and T7 may be n-channel metal oxide semiconductor (NMOS) field-effect transistors (n-channel MOSFETs), and the remaining portion of the plurality of thin-film transistors may be p-channel metal oxide semiconductor (PMOS) field-effect transistors (p-channel MOSFETs). As an example, in an embodiment, among the plurality of thin-film transistors T1, T2, T3, T4, T5, T6, and T7, the compensation transistor T3 and the first initialization transistor T4 may be n-channel MOSFETs (NMOSs), and the remaining portion of the plurality of thin-film transistors may be p-channel MOSFETs (PMOSs). Alternatively, among the plurality of thin-film transistors T1, T2, T3, T4, T5, T6, and T7, the compensation transistor T3, the first initialization transistor T4, and the second initialization transistor T7 may be n-channel MOSFETs (NMOSs), and the remaining portion of the plurality of thin-film transistors may be p-channel MOSFETs (PMOSs). Alternatively, all of the plurality of thin-film transistors T1, T2, T3, T4, T5, T6, and T7 may be NMOSs or PMOSs. In an embodiment, the plurality of thin-film transistors T1, T2, T3, T4, T5, T6, and T7 may each include amorphous silicon or polycrystalline silicon. In some embodiments, a thin-film transistor, which is an NMOS, may include an oxide semiconductor. Hereinafter, for convenience of description, an embodiment in which the compensation transistor T3 and the first initialization transistor T4 are NMOSs including an oxide semiconductor, and the remaining portion of the plurality of thin-film transistors are PMOSs, is described.

In an embodiment, the plurality of signal lines may include a first scan line SL1, a second scan line SL2, a previous scan line SLp, a next scan line SLn, an emission control line EL, and a data line DL. The first scan line SL1 is configured to transfer a first scan signal Sn, the second scan line SL2 is configured to transfer a second scan signal Sn′, the previous scan line SLp is configured to transfer a previous scan signal Sn−1 to the first initialization transistor T4, the next scan line SLn is configured to transfer a next scan signal Sn+1 to the second initialization transistor T7, the emission control line EL is configured to transfer an emission control signal En to the operation control transistor T5 and the emission control transistor T6, and the data line DL crosses the first scan line SL1 and is configured to transfer a data signal Dm.

The driving voltage line PL may be configured to transfer the driving voltage ELVDD to the driving transistor T1, the first initialization voltage line VL1 may be configured to transfer a first initialization voltage Vint1 initializing the driving transistor T1, and the second initialization voltage line VL2 may be configured to transfer a second initialization voltage Vint2 initializing the first electrode of the organic light-emitting diode OLED.

A driving gate electrode of the driving transistor T1 may be connected to the storage capacitor Cst through a second node N2. One of a source region and a drain region of the driving transistor T1 may be connected to a driving voltage line PL through the operation control transistor T5 via a first node N1. The other of the source region and the drain region of the driving transistor T1 may be connected to the first electrode (e.g., the pixel electrode) of the organic light-emitting diode OLED through the emission control transistor T6 via a third node N3. The driving transistor T1 may be configured to receive a data signal Dm and supply the driving current to the organic light-emitting diode OLED according to a switching operation of the switching transistor T2. For example, the driving transistor T1 may be configured to control the amount of current flowing from the first node N1 to the organic light-emitting diode OLED in response to a voltage applied to the second node N2 and changed by a data signal Dm. The first node N1 is electrically connected to the driving voltage line PL.

A switching gate electrode of the switching transistor T2 may be connected to the first scan line SL1 configured to transfer a first scan signal Sn. One of a source region and a drain region of the switching transistor T2 may be connected to the data line DL, and the other of the source region and the drain region of the switching transistor T2 may be connected to the driving transistor T1 through the first node N1 and connected to the driving voltage line PL through the operation control transistor T5. The switching transistor T2 may be configured to transfer a data signal Dm from the data line DL to the first node N1 in response to a voltage applied to the first scan line SL1. For example, the switching transistor T2 may perform a switching operation of being turned on according to a first scan signal Sn transferred through the first scan line SL1 and transferring a data signal Dm to the driving transistor T1 through the first node N1. The data signal Dm is transferred through the data line DL.

A compensation gate electrode of the compensation transistor T3 is connected to the second scan line SL2. One of a source region and a drain region of the compensation transistor T3 may be connected to the first electrode of the organic light-emitting diode OLED through the emission control transistor T6 via the third node N3. The other of the source region and the drain region of the compensation transistor T3 may be connected to a first capacitor electrode CE1 of the storage capacitor Cst, and the driving gate electrode of the driving transistor T1 through the second node N2. The compensation transistor T3 may diode-connect the driving transistor T1 by being turned on according to a second scan signal Sn′ received through the second scan line SL2.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst, and the driving gate electrode of the driving transistor T1 through the second node N2. The first initialization transistor T4 may be configured to apply the first initialization voltage Vint1 from the first initialization voltage line VL1 to the second node N2 according to a voltage applied to the previous scan line SLp. For example, the first initialization transistor T4 may be turned on according to a previous scan signal Sn−1 received through the previous scan line SLp and may perform an initialization operation of initializing the voltage of the driving gate voltage of the driving transistor T1 by transferring the first initialization voltage Vint1 to the driving gate electrode of the driving transistor T1.

An operation control gate electrode of the operation control transistor T5 may be connected to the emission control line EL. One of a source region and a drain region of the operation control transistor T5 may be connected to the driving voltage line PL. The other of the source region and the drain region of the operation control transistor T5 may be connected to the driving transistor T1 and the switching transistor T2 through the first node N1.

An emission control gate electrode of the emission control transistor T6 may be connected to the emission control line EL. One of a source region and a drain region of the emission control transistor T6 may be connected to the driving transistor T1 and the compensation transistor T3 through the third node N3. The other of the source region and the drain region of the emission control transistor T6 may be electrically connected to the first electrode (e.g., the pixel electrode) of the organic light-emitting diode OLED.

In an embodiment, the operation control transistor T5 and the emission control transistor T6 may be simultaneously turned on according to an emission control signal En transferred through the emission control line EL. When the operation control transistor T5 and the emission control transistor T6 are turned on (e.g., simultaneously turned on), the driving voltage ELVDD is transferred to the organic light-emitting diode OLED, and the driving current flows through the organic light-emitting diode OLED.

A second initialization gate electrode of the second initialization transistor T7 may be connected to the next scan line SLn. One of a source region and a drain region of the second initialization transistor T7 may be connected to the first electrode (e.g., the pixel electrode) of the organic light-emitting diode OLED. The other of the source region and the drain region of the second initialization transistor T7 may be electrically connected to the second initialization voltage line VL2 to receive the second initialization voltage Vint2. The second initialization transistor T7 is turned on according to a next scan signal Sn+1 transferred through the next scan line SLn+1 and initializes the first electrode (e.g., the pixel electrode) of the organic light-emitting diode OLED. In an embodiment, the next scan line SLn may be the same as the first scan line SL1. In this embodiment, the relevant scan line may be configured to transfer the same electrical signals with a time difference, and thus, may serve as the first scan line SL1 and the next scan line SLn. For example, in an embodiment the next scan line SLn may be the first scan line of a pixel which is a pixel adjacent to the pixel P shown in FIG. 2 and electrically connected to the data line DL.

As shown in FIG. 2, the second initialization thin-film transistor T7 may be connected to the next scan line SLn. However, embodiments of the present disclosure are not necessarily limited thereto and the second initialization transistor T7 may be connected to the emission control line EL and driven according to an emission control signal En in some embodiments.

The storage capacitor Cst may include the first capacitor electrode CE1 and a second capacitor electrode CE2. The first capacitor electrode CE1 of the storage capacitor Cst is connected to the driving gate electrode of the driving transistor T1 through the second node N2, and the second capacitor electrode CE2 of the storage capacitor Cst is connected to the driving voltage line PL. In an embodiment, the storage capacitor Cst may be configured to store a charge corresponding to a difference between a voltage of the driving gate of the driving transistor T1 and the driving voltage ELVDD.

A specific operation of each pixel P according to an embodiment is described below.

In an embodiment, when a previous scan signal Sn−1 is supplied through the previous scan line SLp during an initialization period, the first initialization transistor T4 is turned on according to the previous scan signal Sn−1, and the driving transistor T1 is initialized by the first initialization voltage Vint1 supplied from the first initialization voltage line VL1.

In an embodiment, when a first scan signal Sn and a second scan signal Sn′ are supplied through the first scan line SL1 and the second scan line SL2, respectively, during a data programming period, the switching transistor T2 and the compensation transistor T3 are turned on according to the first scan signal Sn and the second scan signal Sn′, respectively. In this embodiment, the driving transistor T1 is diode-connected and forward-biased by the compensation transistor T3 that is turned on. In an embodiment, a compensation voltage Dm+Vth (Vth has a (−) value) is then applied to the gate electrode of the driving transistor T1. The compensation voltage Dm+Vth is a voltage reduced by a threshold voltage Vth of the driving transistor T1 from a data signal Dm supplied from the data line DL. The driving voltage ELVDD and the compensation voltage Dm+Vth are respectively applied to two opposite ends of the storage capacitor Cst. A charge corresponding to a difference between the voltages of the two opposite ends is stored in the storage capacitor Cst.

During an emission period, the operation control transistor T5 and the emission control transistor T6 are turned on (e.g., simultaneously turned on) according to an emission control signal En supplied from the emission control line EL. The driving current corresponding to a voltage difference between the voltage of the gate electrode of the driving transistor T1 and the driving voltage ELVDD occurs. The driving current is then supplied to the organic light-emitting diode OLED through the emission control transistor T6.

As described above, some (e.g., a first portion) of the plurality of thin-film transistors T1, T2, T3, T4, T5, T6, and T7 may include an oxide semiconductor. As an example, in an embodiment the compensation transistor T3 and the first initialization transistor T4 may include an oxide semiconductor.

Since polycrystalline silicon has a high reliability, it is possible to accurately control the flow of an intended current. Accordingly, the driving transistor T1 directly influencing the brightness of the display apparatus may be configured to include a semiconductor layer including polycrystalline silicon having high reliability, and thus, a high-resolution display apparatus may be implemented through this configuration. Since an oxide semiconductor has high carrier mobility and a low leakage current, a voltage drop is not large even when a driving time is long. For example, in the oxide semiconductor, since a color change of an image according to a voltage drop is relatively small even while the display apparatus is driven in low frequencies, the display apparatus may be driven in low frequencies. Accordingly, by allowing the compensation transistor T3 and the first initialization transistor T4 to include an oxide semiconductor, a display apparatus in which the occurrence of a leakage current is prevented, and simultaneously, with a reduced power consumption may be implemented.

Since the oxide semiconductor is sensitive to light, a change in the amount of current may occur due to external light. Accordingly, external light may be absorbed or reflected by disposing a metal layer under the oxide semiconductor. Accordingly, as shown in FIG. 2, gate electrodes of each of the compensation transistor T3 and the first initialization transistor T4 may be respectively disposed on and under the oxide semiconductor layer. For example, when viewed in a Z-axis direction, a metal layer disposed under the oxide semiconductor may overlap the oxide semiconductor.

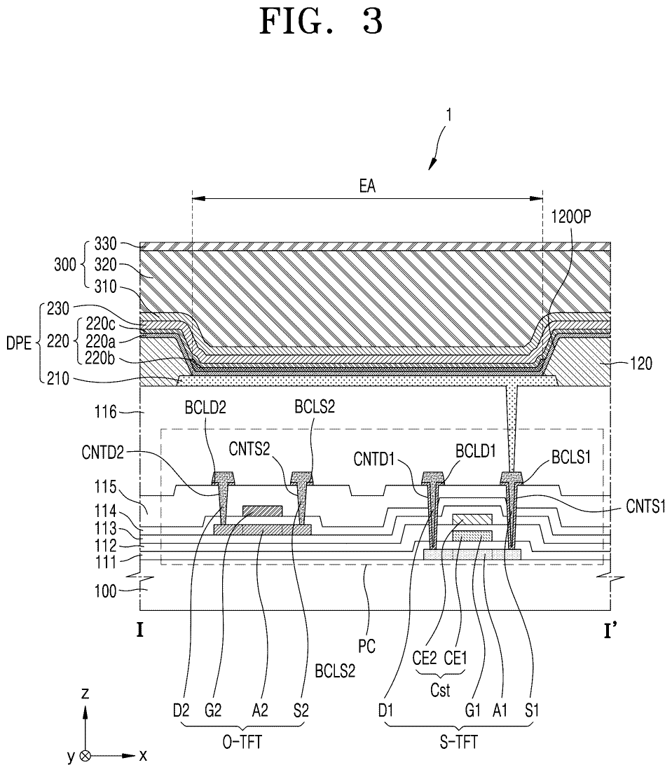

FIG. 3 is a schematic cross-sectional view of the display apparatus 1 of FIG. 1, taken along line I-I′ of FIG. 1.

As shown in FIG. 3, the display apparatus 1 includes the substrate 100. In an embodiment, the substrate 100 may include glass, metal, or polymer resin. The substrate 100 may be flexible or bendable. In an embodiment in which the substrate 100 is flexible or bendable, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, embodiments of the present disclosure are not necessarily limited thereto. In an embodiment, the substrate 100 may have a multi-layered structure including two layers each including the polymer resin, and a barrier layer including an inorganic material (such as silicon oxide (SiOₓ), silicon nitride (SiNₓ), and silicon oxynitride (SiOₓN_{y}) therebetween. However, embodiments of the present disclosure are not necessarily limited thereto.

A display element DPE and the pixel circuit PC may be disposed on the substrate 100. The pixel circuit PC is electrically connected to the display element DPE. In an embodiment, the pixel circuit PC may include at least one silicon thin-film transistor S-TFT, at least one oxide thin-film transistor O-TFT, and the storage capacitor Cst. It is shown in FIG. 3 that an organic light-emitting diode as a display element DPE is located over the substrate 100. When the display element DPE is electrically connected to the pixel circuit PC, a pixel electrode 210 of the display element DPE may be electrically connected to thin-film transistors of the pixel circuit PC.

As described above, although the pixel circuit PC may include the driving transistor T1, the switching transistor T2, the compensation transistor T3, the first initialization transistor T4, the operation control transistor T5, the emission control transistor T6, and the second initialization transistor T7, FIG. 3 shows, for convenience of description, only some of the driving transistor T1, the switching transistor T2, the compensation transistor T3, the first initialization transistor T4, the operation control transistor T5, the emission control transistor T6, and the second initialization transistor T7. As an example, in an embodiment, the silicon thin-film transistor S-TFT shown in FIG. 3 may be the driving transistor T1, and the oxide thin-film transistor O-TFT shown in FIG. 3 may be the compensation transistor T3.

The silicon thin-film transistor S-TFT may be disposed on the substrate 100. As shown in FIG. 3, the silicon thin-film transistor S-TFT may include a first semiconductor layer A1, a first gate electrode G1, a 1st-1 connection electrode S1, and a 1st-2 connection electrode D1. As an example, in an embodiment the 1st-1 connection electrode S1 may be a source electrode, and the 1st-2 connection electrode D1 may be a drain electrode. Alternatively, the 1st-1 connection electrode S1 may be a drain electrode, and the 1st-2 connection electrode D1 may be a source electrode depending on the polarity of the silicon thin-film transistor S-TFT.

In an embodiment, the first semiconductor layer A1 may be disposed on (e.g., directly thereon in the Z direction) the substrate 100. The first semiconductor layer A1 may include a silicon semiconductor. In an embodiment, the silicon semiconductor may include amorphous silicon or polycrystalline silicon. As an example, the first semiconductor layer A1 may include low temperature polycrystalline silicon (LTPS). The first semiconductor layer A1 may include a first channel region, a first source region, and a first drain region. The first source region and the first drain region may be respectively disposed on two opposite sides of the first channel region (e.g., in the X-axis direction). The first source region and the first drain region may be doped with impurities. The impurities may include N-type impurities or P-type impurities. In an embodiment, the first channel region may overlap the first gate electrode G1 (e.g., in the Z-axis direction) and may not be doped with impurities or may include a very small amount of impurities. The first source region may be electrically connected to the 1st-1 connection electrode S1, and the first drain region may be electrically connected to the 1st-2 connection electrode D1.

In an embodiment, a first inorganic insulating layer 111 may be disposed on the first semiconductor layer A1 (e.g., disposed directly thereon in the Z direction). The first inorganic insulating layer 111 may include an inorganic material. As an example, in an embodiment the first inorganic insulating layer 111 may include an inorganic insulating material such as silicon oxide (SiOₓ), silicon nitride (SiNₓ), or silicon oxynitride (SiOₓN_{y}), and may have a single-layered or multi-layered structure including the above materials.

The first gate electrode G1 may be disposed on the first inorganic insulating layer 111. For example, the first gate electrode G1 may be disposed over the first semiconductor layer A1 (e.g., in the Z-axis direction), and the first inorganic insulating layer 111 may be disposed between the first semiconductor layer A1 and the first gate electrode G1 (e.g., in the Z-axis direction). The gate electrode G1 may at least partially overlap the semiconductor layer A1 (e.g., in the Z-axis direction). As an example, the first gate electrode G1 may overlap the first channel region of the first semiconductor layer A1 (e.g., in the Z-axis direction). In an embodiment, the first gate electrode G1 of the silicon thin-film transistor S-TFT may include a conductive material of a low-resistance such as molybdenum (Mo), aluminum (Al), copper (Cu) and/or titanium (Ti), and have a single-layered structure or a multi-layered structure including the above materials. As an example, the first gate electrode G1 may include a single Mo layer or a multi-layered structure of Mo/Al/Mo. However, embodiments of the present disclosure are not necessarily limited thereto.

The storage capacitor Cst may include the first capacitor electrode CE1 and the second capacitor electrode CE2. In an embodiment, the storage capacitor Cst may be formed to overlap the silicon thin-film transistor S-TFT (e.g., in the Z-axis direction). In this embodiment, the first gate electrode G1 may serve not only as the gate electrode of the silicon thin-film transistor S-TFT but also as the first capacitor electrode CE1, simultaneously. For example, in an embodiment the first gate electrode G1 may be integrally provided with the first capacitor electrode CE1. In an embodiment, the first capacitor electrode CE1 may be formed as an electrode of an island shape. However, embodiments of the present disclosure are not necessarily limited thereto. For example, in an embodiment, the storage capacitor Cst may be provided separately and may not overlap the silicon thin-film transistor S-TFT (e.g., in the Z-axis direction).

A second inorganic insulating layer 112 may be disposed on the first gate electrode G1 (e.g., disposed directly thereon). The second inorganic insulating layer 112 may include an inorganic material. As an example, in an embodiment the second inorganic insulating layer 112 may include an inorganic insulating material such as silicon oxide (SiOₓ), silicon nitride (SiNₓ), or silicon oxynitride (SiOₓN_{y}), and may have a single-layered or multi-layered structure including the above materials. However, embodiments of the present disclosure are not necessarily limited thereto.

The second capacitor electrode CE2 may be disposed on the second inorganic insulating layer 112 (e.g., disposed directly thereon in the Z-axis direction). For example, the second capacitor electrode CE2 may be disposed on the second inorganic insulating layer 112 to overlap the first capacitor electrode CE1 (e.g., in the Z-axis direction). For example, the second capacitor electrode CE2 may be disposed over the first capacitor electrode CE1 to overlap the first capacitor electrode CE1 (e.g., in the Z-axis direction), and the second inorganic insulating layer 112 may be disposed between the first capacitor electrode CE1 and the second capacitor electrode CE2 (e.g., in the Z-axis direction). The second inorganic insulating layer 112 may serve as a dielectric layer of the storage capacitor Cst.

The second capacitor electrode CE2 may include metal, an alloy, a conductive metal oxide, or a transparent conductive material and the like. In an embodiment, the second capacitor electrode CE2 may include, for example, at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), and include a single layer or a multi-layered structure including the above materials. However, embodiments of the present disclosure are not necessarily limited thereto.

A third inorganic insulating layer 113 may be disposed on the second capacitor electrode CE2 (e.g., disposed directly thereon in the Z-axis direction). The third inorganic insulating layer 113 may include an inorganic material. As an example, in an embodiment the third inorganic insulating layer 113 may include an inorganic insulating material such as silicon oxide (SiOₓ), silicon nitride (SiNₓ), or silicon oxynitride (SiOₓN_{y}), and may have a single-layered or multi-layered structure including the above materials. However, embodiments of the present disclosure are not necessarily limited thereto.

The oxide thin-film transistor O-TFT may be disposed on the third inorganic insulating layer 113 (e.g., disposed directly thereon in the Z-axis direction). As shown in FIG. 3, in an embodiment the oxide thin-film transistor O-TFT may include a second semiconductor layer A2, a second gate electrode G2, a 2nd-1 connection electrode S2, and a 2nd-2 connection electrode D2. As an example, in an embodiment the 2nd-1 connection electrode S2 may be a source electrode, and the 2nd-2 connection electrode D2 may be a drain electrode. Alternatively, the 2nd-1 connection electrode S2 may be a drain electrode, and the 2nd-2 connection electrode D2 may be a source electrode depending on the polarity of the oxide thin-film transistor O-TFT.

In an embodiment, the second semiconductor layer A2 may be disposed on the third inorganic insulating layer 113 (e.g., disposed directly thereon in the Z-axis direction). The second semiconductor layer A2 may include a material different from the first semiconductor layer A1. As an example, the second semiconductor layer A2 may include an oxide semiconductor. In an embodiment, the oxide semiconductor is a Zn oxide-based material and may include Zn oxide, In—Zn oxide, or Ga—In—Zn oxide. In an embodiment, the oxide semiconductor may include In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO. However, embodiments of the present disclosure are not necessarily limited thereto. In an embodiment, the second semiconductor layer A2 may include a second channel region, a second source region, and a second drain region. The second source region and the second drain region are disposed on two opposite sides of the second channel region (e.g., in the X-axis direction). In an embodiment, the second source region may be electrically connected to the 2nd-1 connection electrode S2, and the second drain region may be electrically connected to the 2nd-2 connection electrode D2.

In an embodiment, a fourth inorganic insulating layer 114 may be disposed on the second semiconductor layer A2 (e.g., disposed directly thereon in the Z-axis direction). The fourth inorganic insulating layer 114 may include an inorganic material. As an example, in an embodiment the fourth inorganic insulating layer 114 may include an inorganic insulating material such as silicon oxide (SiOₓ), silicon nitride (SiNₓ), or silicon oxynitride (SiOₓN_{y}), and may have a single-layered or multi-layered structure including the above materials.

The second gate electrode G2 may be disposed on the fourth inorganic insulating layer 114 (e.g., disposed directly thereon in the Z-axis direction). For example, the second gate electrode G2 may be disposed over the second semiconductor layer A2, and the fourth inorganic insulating layer 114 may be disposed between the second semiconductor layer A2 and the second gate electrode G2 (e.g., in the Z-axis direction). The second gate electrode G2 may at least partially overlap the second semiconductor layer A2 (e.g., in the Z-axis direction). As an example, the second gate electrode G2 may overlap the second channel region of the second semiconductor layer A2 (e.g., in the Z-axis direction). In an embodiment, the second gate electrode G2 of the oxide thin-film transistor O-TFT may include a conductive material of a low-resistance material such as molybdenum (Mo), aluminum (Al), copper (Cu) and/or titanium (Ti), and have a single-layered structure or a multi-layered structure including the above materials. As an example, the second gate electrode G2 may include a single Mo layer or a multi-layered structure of Mo/Al/Mo. However, embodiments of the present disclosure are not necessarily limited thereto.

In an embodiment, a fifth inorganic insulating layer 115 may be disposed on the second gate electrode G2 (e.g., disposed directly thereon). The fifth inorganic insulating layer 115 may cover the oxide thin-film transistor O-TFT. The fifth inorganic insulating layer 115 may include an inorganic material. As an example, in an embodiment the fifth inorganic insulating layer 115 may include an inorganic insulating material such as silicon oxide (SiOₓ), silicon nitride (SiNₓ), or silicon oxynitride (SiOₓN_{y}), and may have a single-layered or multi-layered structure including the above materials. However, embodiments of the present disclosure are not necessarily limited thereto.

The 1st-1 connection electrode S1, the 1st-2 connection electrode D1, the 2nd-1 connection electrode S2, and the 2nd-2 connection electrode D2 may be disposed over (e.g., directly over) the fifth inorganic insulating layer 115. Each of the 1st-1 connection electrode S1, the 1st-2 connection electrode D1, the 2nd-1 connection electrode S2, and the 2nd-2 connection electrode D2 may include a conductive material. As an example, in an embodiment each of the 1st-1 connection electrode S1, the 1st-2 connection electrode D1, the 2nd-1 connection electrode S2, and the 2nd-2 connection electrode D2 may include a metal material such as molybdenum (Mo), aluminum (Al), copper (Cu), or titanium (Ti), and may have a single layer or a multi-layered structure including the above materials. As an example, each of the 1st-1 connection electrode S1, the 1st-2 connection electrode D1, the 2nd-1 connection electrode S2, and the 2nd-2 connection electrode D2 may have a multi-layered structure of Ti/Al/Ti. However, embodiments of the present disclosure are not necessarily limited thereto.

The connection electrodes may be electrically connected to the semiconductor layers through contact holes formed in the inorganic insulating layers. For example, in an embodiment a 1st-1 contact hole CNTS1 and a 1st-2 contact hole CNTD1 may be formed in the first inorganic insulating layer 111, the second inorganic insulating layer 112, the third inorganic insulating layer 113, the fourth inorganic insulating layer 114, and the fifth inorganic insulating layer 115. For example, the 1st-1 contact hole CNTS1 may pass through the first inorganic insulating layer 111, the second inorganic insulating layer 112, the third inorganic insulating layer 113, the fourth inorganic insulating layer 114, and the fifth inorganic insulating layer 115 (e.g., in the Z-axis direction). The 1st-1 connection electrode S1 may be electrically connected to the first semiconductor layer A1 through the 1st-1 contact hole CNTS1. The 1st-2 contact hole CNTD1 may pass through the first inorganic insulating layer 111, the second inorganic insulating layer 112, the third inorganic insulating layer 113, the fourth inorganic insulating layer 114, and the fifth inorganic insulating layer 115 (e.g., in the Z-axis direction). The 1st-2 connection electrode D1 may be electrically connected to the first semiconductor layer A1 through the 1st-2 contact hole CNTD1. For example, the 1st-1 connection electrode S1 may be electrically connected to the source region of the first semiconductor layer A1 through the 1st-1 contact hole CNTS1, and the 1st-2 connection electrode D1 may be electrically connected to the drain region of the first semiconductor layer A1 through the 1st-2 contact hole CNTD1.

In addition, a 2nd-1 contact hole CNTS2 and a 2nd-2 contact hole CNTD2 may be formed in the fourth inorganic insulating layer 114, and the fifth inorganic insulating layer 115. For example, the 2nd-1 contact hole CNTS2 may pass through the fourth inorganic insulating layer 114 and the fifth inorganic insulating layer 115 (e.g., in the Z-axis direction). The 2nd-1 connection electrode S2 may be electrically connected to the second semiconductor layer A2 through the 2nd-1 contact hole CNTS2. The 2nd-2 contact hole CNTD2 may pass through the fourth inorganic insulating layer 114 and the fifth inorganic insulating layer 115 (e.g., in the Z-axis direction). The 2nd-2 connection electrode D2 may be electrically connected to the second semiconductor layer A2 through the 2nd-2 contact hole CNTD2. For example, the 2nd-1 connection electrode S2 may be electrically connected to the source region of the second semiconductor layer A2 through the 2nd-1 contact hole CNTS2, and the 2nd-2 connection electrode D2 may be electrically connected to the drain region of the second semiconductor layer A2 through the 2nd-2 contact hole CNTD2.

However, embodiments of the present disclosure are not necessarily limited thereto. As an example, the silicon thin-film transistor S-TFT may include only one of the 1st-1 connection electrode S1 and the 1st-2 connection electrode D1, or may not include both. As an example, in an embodiment a silicon thin-film transistor S-TFT may not include the 1st-2 connection electrode D1, another silicon thin-film transistor S-TFT connected to this silicon thin-film transistor S-TFT may not include the 1st-1 connection electrode S1, and the first semiconductor layers A1 of these two silicon thin-film transistors S-TFT may be connected to each other. This connection structure may have the same effect in which a silicon thin-film transistor S-TFT has the 1st-2 connection electrode D1, another silicon thin-film transistor S-TFT has the 1st-1 connection electrode S1, and the 1st-2 connection electrode D1 of the silicon thin-film transistor S-TFT is connected to the 1st-1 connection electrode S1 of the other silicon thin-film transistor S-TFT.

Similarly, in an embodiment the oxide thin-film transistor O-TFT may include only one of the 2nd-1 connection electrode S2 and the 2nd-2 connection electrode D2, or may not include both. As an example, an oxide thin-film transistor O-TFT may not include the 2nd-2 connection electrode D2, another oxide thin-film transistor O-TFT connected to this oxide thin-film transistor O-TFT may not include the 2nd-1 connection electrode S2, and the second semiconductor layers A2 of these two oxide thin-film transistors O-TFT may be connected to each other. This connection structure may have the same effect in which an oxide thin-film transistor O-TFT has the 2nd-2 connection electrode D2, another oxide thin-film transistor O-TFT has the 2nd-1 connection electrode S2, and the 2nd-2 connection electrode D2 of the oxide thin-film transistor O-TFT is connected to the 2nd-1 connection electrode S2 of the other oxide thin-film transistor O-TFT.

Bridge contact layers may be disposed between the fifth inorganic insulating layer 115, the 1st-1 connection electrode S1, the 1st-2 connection electrode D1, the 2nd-1 connection electrode S2, and the 2nd-2 connection electrode D2. The bridge contact layers are described below in detail.

In an embodiment, the silicon thin-film transistor S-TFT and the oxide thin-film transistor O-TFT may be covered by (e.g., directly covered by) an organic insulating layer 116. As an example, the organic insulating layer 116 may cover (e.g., directly cover) the 1st-1 connection electrode S1, the 1st-2 connection electrode D1, the 2nd-1 connection electrode S2, and the 2nd-2 connection electrode D2. For example, the organic insulating layer 116 may be disposed on the 1st-1 connection electrode S1, the 1st-2 connection electrode D1, the 2nd-1 connection electrode S2, and the 2nd-2 connection electrode D2. The display element DPE may be disposed on the organic insulating layer 116.

The organic insulating layer 116 is a planarization insulating layer and may include an approximately flat upper surface. Accordingly, the organic insulating layer 116 may provide the flat upper surface such that the pixel electrode 210 of the display element DPE is formed flat. The organic insulating layer 116 may include an organic insulating material. As an example, in an embodiment the organic insulating layer 116 may include a general-purpose polymer such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. However, embodiments of the present disclosure are not necessarily limited thereto. The organic insulating layer 116 may include a single layer or a multi-layered structure including the above materials.

As described above, the display element DPE may be disposed on (e.g., disposed directly thereon in the Z-axis direction) the organic insulating layer 116. In an embodiment, the display element DPE may be an organic light-emitting diode including the pixel electrode 210, an opposite electrode 230, and an intermediate layer 220. The intermediate layer 220 is disposed between the pixel electrode 210 and the opposite electrode 230 (e.g., in the Z-axis direction) and includes an emission layer. As described above, the display element DPE may be electrically connected to the pixel circuit PC. When the display element DPE is electrically connected to the pixel circuit PC, the pixel electrode 210 of the display element DPE is electrically connected to the pixel circuit PC. For example, in an embodiment the pixel electrode 210 may be electrically connected to the silicon thin-film transistor S-TFT by being in direct contact with one of the 1st-1 connection electrode S1 and the 1st-2 connection electrode D1 through a contact hole formed in the organic insulating layer 116. Although it is shown in FIG. 3 that the pixel electrode 210 is in contact with the 1st-1 connection electrode S1 through a contact hole formed in the organic insulating layer 116, embodiments of the present disclosure are not necessarily limited thereto. For example, in an embodiment, the pixel electrode 210 may be in direct contact with the 1st-2 connection electrode D1 through the contact hole formed in the organic insulating layer 116 in some embodiments.

In an embodiment, the pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). However, embodiments of the present disclosure are not necessarily limited thereto. For example, in an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In an embodiment, the pixel electrode 210 may further include a layer on/under the reflective layer, the layer including ITO, IZO, ZnO, or In₂O₃. As an example, the pixel electrode 210 may have a three-layered structure of ITO/Ag/ITO. However, embodiments of the present disclosure are not necessarily limited thereto.

A pixel-defining layer 120 may be disposed on the organic insulating layer 116 (e.g., disposed directly thereon in the Z-axis direction). In an embodiment, the pixel-defining layer 120 may cover the edges (e.g., lateral edges) of the pixel electrode 210 and may expose a central portion of the pixel electrode 210. The pixel-defining layer 120 may include a pixel opening 1200P, and the pixel opening 1200P may overlap the pixel electrode 210 (e.g., in the Z-axis direction), such as the central portion of the pixel electrode 210. The pixel opening 1200P may define an emission area of light emitted from the display element DPE. The pixel-defining layer 120 may include an organic insulating material and/or an inorganic insulating material. In an embodiment, the pixel-defining layer 120 may include a light-blocking material.

The intermediate layer 220 may be disposed on the pixel electrode 210 and the pixel-defining layer 120 (e.g., in the Z-axis direction). The intermediate layer 220 may include an emission layer 220b. In an embodiment, the emission layer 220b may include an organic material including a fluorescent or phosphorous material configured to emit red, green, or blue light. The emission layer 220b may include a low-molecular weight organic material or a polymer organic material. A first functional layer 220a and a second functional layer 220c may be selectively further arranged under and on the emission layer 220b (e.g., in the Z-axis direction). The first functional layer 220a includes a hole transport layer (HTL) and a hole injection layer (HIL). The second functional layer 220c includes an electron transport layer (ETL) and an electron injection layer (EIL). In an embodiment, the intermediate layer 220 may be formed by screen printing, inkjet printing, laser induced thermal imaging (LITI), or the like. However, the intermediate layer 220 is not necessarily limited thereto but may have various structures. The intermediate layer 220 may include a layer, which is one body (e.g., commonly disposed) over the plurality of pixel electrodes 210, or include a layer patterned to correspond to each of the plurality of pixel electrodes 210.

The opposite electrode 230 may be disposed on the intermediate layer 220 (e.g., in the Z-axis direction). In an embodiment, the opposite electrode 230 may be formed as one body (e.g., commonly disposed) over a plurality of organic light-emitting diodes to correspond to a plurality of pixel electrodes 210. In an embodiment, the opposite electrode 230 may include a light-transmissive conductive layer including ITO, In₂O₃, or IZO, and include a semi-transmissive layer including metal such as aluminum (Al) or silver (Ag). As an example, the opposite electrode 230 may be a semi-transmissive layer including magnesium (Mg) and silver (Ag). However, embodiments of the present disclosure are not necessarily limited thereto.

Since the display element DPE may be easily damaged by external moisture, oxygen, or the like, an encapsulation layer 300 may protect the display element DPE by covering the display element DPE. As shown in FIG. 3, in an embodiment the encapsulation layer 300 may include a first inorganic encapsulation layer 310, an organic encapsulation layer 320, and a second inorganic encapsulation layer 330.

In an embodiment, the first inorganic encapsulation layer 310 may cover the opposite electrode 230 and may include silicon oxide (SiOₓ), silicon nitride (SiNₓ), and/or silicon oxynitride (SiOₓN_{y}). In some embodiments, other layers including a capping layer may be disposed between the first inorganic encapsulation layer 310 and the opposite electrode 230 (e.g., in the Z-axis direction). Since the first inorganic encapsulation layer 310 is formed along a structure thereunder, the upper surface of the first inorganic encapsulation layer 610 may not be flat as shown in FIG. 3. The organic encapsulation layer 320 may cover the first inorganic encapsulation layer 310 and, unlike the first inorganic encapsulation layer 310, the upper surface of the organic encapsulation layer 320 may be approximately flat. In an embodiment, the organic encapsulation layer 320 may include at least one of polyethylene terephthalate, polyethylene naphthalate, polycarbonate, polyimide, polyethylene sulfonate, polyoxymethylene, polyarylate, and hexamethyldisiloxane. However, embodiments of the present disclosure are not necessarily limited thereto. In an embodiment, the second inorganic encapsulation layer 330 may cover the organic encapsulation layer 320 and may include silicon oxide (SiOₓ), silicon nitride (SiNₓ), and/or silicon oxynitride (SiOₓN_{y}). However, embodiments of the present disclosure are not necessarily limited thereto.

Since the encapsulation layer 300 includes the first inorganic encapsulation layer 310, the organic encapsulation layer 320, and the second inorganic encapsulation layer 330, even when cracks occur inside the encapsulation layer 300, the cracks may not be connected between the first inorganic encapsulation layer 310 and the organic encapsulation layer 320 or between the organic encapsulation layer 320 and the second inorganic encapsulation layer 330 through the above multi-layered structure. With this configuration, forming of a path through which external moisture or oxygen penetrates the inside of a display panel 10 may be prevented or reduced.

As described above, the 1st-1 connection electrode S1, the 1st-2 connection electrode D1, the 2nd-1 connection electrode S2, and the 2nd-2 connection electrode D2 may be disposed over (e.g., directly over) the fifth inorganic insulating layer 115. In an embodiment, a bridge contact layer may be disposed between the fifth inorganic insulating layer 115 and each of the 1st-1 connection electrode S1, the 1st-2 connection electrode D1, the 2nd-1 connection electrode S2, and the 2nd-2 connection electrode D2. For example, each of the 1st-1 connection electrode S1, the 1st-2 connection electrode D1, the 2nd-1 connection electrode S2, and the 2nd-2 connection electrode D2 may be disposed on (e.g., disposed directly thereon) the bridge contact layers.

In an embodiment, the 1st-1 connection electrode S1 may be disposed on (e.g., disposed directly thereon) a 1st-1 bridge contact layer BCLS1. The 1st-1 bridge contact layer BCLS1 may cover a portion of the fifth inorganic insulating layer 115, the inner surface of the 1st-1 contact hole CNTS1, and a portion of the first semiconductor layer A1 corresponding to (e.g., exposed by) the 1st-1 contact hole CNTS1. For example, the 1st-1 bridge contact layer BCLS1 may be disposed on (e.g., disposed directly thereon) a portion of the fifth inorganic insulating layer 115, the inner surface of the 1st-1 contact hole CNTS1, and a portion of the first semiconductor layer A1. The 1st-1 bridge contact layer BCLS1 may cover a portion of the upper surface of the fifth inorganic insulating layer 115, the inner surface of the 1st-1 contact hole CNTS1, and a portion of the upper surface of the first semiconductor layer A1 corresponding to (e.g., exposed by) the 1st-1 contact hole CNTS1. Accordingly, the 1st-1 bridge contact layer BCLS1 may be disposed between a portion of the 1st-1 connection electrode S1 and a portion of the fifth inorganic insulating layer 115.

In an embodiment, the inner surface of the 1st-1 contact hole CNTS1 may be covered by the 1st-1 bridge contact layer BCLS1, and a portion of the first semiconductor layer A1 corresponding to (e.g., exposed by) the 1st-1 contact hole CNTS1 may be also covered by the 1st-1 bridge contact layer BCLS1. A portion of the 1st-1 connection electrode S1 may fill the 1st-1 contact hole CNTS1. Accordingly, the 1st-1 connection electrode S1 may be disposed on (e.g., disposed directly thereon) the 1st-1 bridge contact layer BCLS1.

As described above, the 1st-1 connection electrode S1 may be connected to the first semiconductor layer A1 through the 1st-1 contact hole CNTS1 formed in the first inorganic insulating layer 111, the second inorganic insulating layer 112, the third inorganic insulating layer 113, the fourth inorganic insulating layer 114, and the fifth inorganic insulating layer 115. The 1st-1 connection electrode S1 may be in surface contact with the 1st-1 bridge contact layer BCLS1. For example, the 1st-1 bridge contact layer BCLS1 disposed under the 1st-1 connection electrode S1 may have a shape corresponding to the lower surface of the 1st-1 connection electrode S1. The 1st-1 bridge contact layer BCLS1 may conformally cover side surfaces and lower surfaces of the 1st-1 connection electrode S1. For example, the 1st-1 bridge contact layer BCLS1 may be in direct contact with the first semiconductor layer A1, and the 1st-1 connection electrode S1 may be in direct contact with the 1st-1 bridge contact layer BCLS1. Accordingly, the 1st-1 connection electrode S1 may be electrically connected to the first semiconductor layer A1. The above description made on the position relationship between the 1st-1 connection electrode S1 and the 1st-1 bridge contact layer BCLS1 is also applicable to the position relationship between a 1st-2 bridge contact layer BCLD1 and the 1st-2 contact hole CNTD1. Accordingly, with regard to this, repeated descriptions are omitted for economy of description.

In an embodiment, the 1st-2 connection electrode D1 may be disposed on (e.g., disposed directly thereon) the 1st-2 bridge contact layer BCLD1. The 1st-2 bridge contact layer BCLD1 may cover a portion of the fifth inorganic insulating layer 115, the inner surface of the 1st-2 contact hole CNTD1, and a portion of the first semiconductor layer A1 corresponding to (e.g., exposed by) the 1st-2 contact hole CNTD1. For example, the inner surface of the 1st-2 contact hole CNTD1 may be covered by the 1st-2 bridge contact layer BCLD1, and a portion of the first semiconductor layer A1 corresponding to (e.g., exposed by) the 1st-2 contact hole CNTD1 may be also covered by the 1st-2 bridge contact layer BCLD1. A portion of the 1st-2 connection electrode D1 may fill the 1st-2 contact hole CNTD1. Accordingly, the 1st-2 connection electrode D1 may be disposed on (e.g., disposed directly thereon) the 1st-2 bridge contact layer BCLD1. For example, the 1st-2 bridge contact layer BCLD1 may be in direct contact with the first semiconductor layer A1, and the 1st-2 connection electrode D1 may be in direct contact with the 1st-2 bridge contact layer BCLD1.

In an embodiment, the 1st-1 bridge contact layer BCLS1 and the 1st-2 bridge contact layer BCLD1 may include amorphous silicon doped with impurities, and the impurities may include N-type impurities or P-type impurities. As an example, in an embodiment the 1st-1 bridge contact layer BCLS1 and the 1st-2 bridge contact layer BCLD1 may include p-type amorphous silicon doped with impurities such as boron (B), aluminum (Al), or indium (In). Alternatively, the 1st-1 bridge contact layer BCLS1 and the 1st-2 bridge contact layer BCLD1 may include n-type amorphous silicon doped with impurities such as phosphorus (P), arsenic (As), or antimony (Sb). However, embodiments of the present disclosure are not necessarily limited thereto.

In an embodiment, the 1st-1 bridge contact layer BCLS1 and the 1st-2 bridge contact layer BCLD1 may include a metal material. As an example, the 1st-1 bridge contact layer BCLS1 and the 1st-2 bridge contact layer BCLD1 may include tungsten (W). In an embodiment, the 1st-1 bridge contact layer BCLS1 and the 1st-2 bridge contact layer BCLD1 may include conductive metal nitride. As an example, the 1st-1 bridge contact layer BCLS1 and the 1st-2 bridge contact layer BCLD1 may include titanium nitride (TiN). Accordingly, the 1st-1 bridge contact layer BCLS1 and the 1st-2 bridge contact layer BCLD1 may have conductivity.

As described below, in an embodiment the 1st-1 bridge contact layer BCLS1 and the 1st-2 bridge contact layer BCLD1 may be formed by chemical vapor deposition (CVD). Accordingly, the 1st-1 bridge contact layer BCLS1 and the 1st-2 bridge contact layer BCLD1 may have excellent step coverage. Accordingly, each of the 1st-1 bridge contact layer BCLS1 and the 1st-2 bridge contact layer BCLD1 may cover the entire inner surface of the 1st-1 contact hole CNTS1 and the entire inner surface of the 1st-2 contact hole CNTD1. Each of the 1st-1 bridge contact layer BCLS1 and the 1st-2 bridge contact layer BCLD1 may cover a portion of the upper surface of the first semiconductor layer A1. Accordingly, each of the 1st-1 bridge contact layer BCLS1 and the 1st-2 bridge contact layer BCLD1 may not be disconnected inside each of the 1st-1 contact hole CNTS1 and the 1st-2 contact hole CNTD1.

Generally, a layer including a metal material is formed using a sputtering method. The sputtering method has a higher anisotropy than the chemical vapor deposition (CVD). Accordingly, in the case of filling a contact hole having a long shape in a thickness direction (e.g., the +z direction or the −z direction) with a layer including a metal material using the sputtering method, a portion of the inner surface of the contact hole may not be covered by the layer including the metal material. For example, the layer including the metal material may be disconnected inside the contact hole. For example, since the connection electrode includes the metal material, a portion of the inner surface of the contact hole having a long shape in the thickness direction (e.g., +z direction or −z direction) may not be covered by the connection electrode. Accordingly, the connection electrode may be disconnected. Thus, the connection electrode may not be electrically connected to the semiconductor layer.

However, even in the present embodiment, the 1st-1 contact hole CNTS1 and the 1st-2 contact hole CNTD1 may have a long shape in the thickness direction (e.g., +z direction or −z direction). For example, the distance of the 1st-1 contact hole CNTS1 in the thickness direction (e.g., +z direction or −z direction) may be greater than the width of the 1st-1 contact hole CNTS1 when viewed in an xy plane. The distance of the 1st-2 contact hole CNTD1 in the thickness direction (e.g., +z direction or −z direction) may be greater than the width of the 1st-2 contact hole CNTD1 when viewed in the xy plane. The 1st-1 bridge contact layer BCLS1 and the 1st-2 bridge contact layer BCLD1 each having conductivity and excellent step coverage may be respectively disposed under (e.g., disposed directly thereunder) the 1st-1 connection electrode S1 and the 1st-2 connection electrode D1. Accordingly, each of the 1st-1 connection electrode S1 and the 1st-2 connection electrode D1 may be electrically connected to the first semiconductor layer A1.

The 2nd-1 connection electrode S2 may be disposed on (e.g., disposed directly thereon) the 2nd-1 bridge contact layer BCLS2. For example, the 2nd-1 connection electrode S2 may be disposed on a 2nd-1 bridge contact layer BCLS2. The 2nd-1 bridge contact layer BCLS2 may cover a portion of the fifth inorganic insulating layer 115. For example, the 2nd-1 bridge contact layer BCLS2 may be disposed on (e.g., disposed directly thereon) a portion of the fifth inorganic insulating layer 115. Thus, the 2nd-1 bridge contact layer BCLS2 may cover a portion of the upper surface of the fifth inorganic insulating layer 115. Accordingly, the 2nd-1 bridge contact layer BCLS2 may be disposed between a portion of the 2nd-1 connection electrode S2 and a portion of the fifth inorganic insulating layer 115.

However, the inner surface of the 2nd-1 contact hole CNTS2 may not be covered by the 2nd-1 bridge contact layer BCLS2, and a portion of the second semiconductor layer A2 corresponding to the 2nd-1 contact hole CNTS2 may not be also covered by the 2nd-1 bridge contact layer BCLS2. A portion of the 2nd-1 connection electrode S2 may fill the 2nd-1 contact hole CNTS2. Accordingly, another portion of the 2nd-1 connection electrode S2 may not be disposed on the 2nd-1 bridge contact layer BCLS2.

As described above, the 2nd-1 connection electrode S2 may be connected to the second semiconductor layer A2 through the 2nd-1 contact hole CNTS2 formed in the fourth inorganic insulating layer 114 and the fifth inorganic insulating layer 115. For example, the 2nd-1 connection electrode S2 may be in direct contact with the second semiconductor layer A2. Accordingly, the 2nd-1 connection electrode S2 may be electrically connected to the second semiconductor layer A2. The 2nd-1 bridge contact layer BCLS2 may not be in direct contact with the second semiconductor layer A2. For example, the 2nd-1 bridge contact layer BCLS2 may be spaced apart from the second semiconductor layer A2 (e.g., in the Z-axis direction). The above description made on the position relationship between the 2nd-1 connection electrode S2 and the 2nd-1 bridge contact layer BCLS2 is also applicable to the position relationship between a 2nd-2 bridge contact layer BCLD2 and the 2nd-2 contact hole CNTD2. Accordingly, with regard to this, repeated descriptions are omitted for economy of description.

In an embodiment, the 2nd-2 connection electrode D2 may be disposed on (e.g., disposed directly thereon) the 2nd-2 bridge contact layer BCLD2. The 2nd-2 bridge contact layer BCLD2 may cover a portion of the fifth inorganic insulating layer 115. The inner surface of the 2nd-2 contact hole CNTD2 may not be covered by the 2nd-2 bridge contact layer BCLD2, and a portion of the second semiconductor layer A2 corresponding to the 2nd-2 contact hole CNTD2 may not be also covered by the 2nd-2 bridge contact layer BCLD2. A portion of the 2nd-2 connection electrode D2 may fill the 2nd-2 contact hole CNTD2. Accordingly, another portion of the 2nd-2 connection electrode D2 may not be disposed on the 2nd-2 bridge contact layer BCLD2. The 2nd-2 connection electrode D2 may be in direct contact with the second semiconductor layer A2.

In an embodiment, the 2nd-1 bridge contact layer BCLS2 and the 2nd-2 bridge contact layer BCLD2 may include the same material as the 1st-1 bridge contact layer BCLS1 and the 1st-2 bridge contact layer BCLD1. As an example, the 2nd-1 bridge contact layer BCLS2 and the 2nd-2 bridge contact layer BCLD2 may include p-type amorphous silicon doped with impurities such as boron (B), aluminum (Al), or indium (In). Alternatively, the 2nd-1 bridge contact layer BCLS2 and the 2nd-2 bridge contact layer BCLD2 may include n-type amorphous silicon doped with impurities such as phosphorus (P), arsenic (As), or antimony (Sb). Alternatively, the 2nd-1 bridge contact layer BCLS2 and the 2nd-2 bridge contact layer BCLD2 may include a metal material. As an example, the 2nd-1 bridge contact layer BCLS2 and the 2nd-2 bridge contact layer BCLD2 may include tungsten (W). Alternatively, the 2nd-1 bridge contact layer BCLS2 and the 2nd-2 bridge contact layer BCLD2 may include conductive metal nitride. As an example, the 2nd-1 bridge contact layer BCLS2 and the 2nd-2 bridge contact layer BCLD2 may include titanium nitride (TiN). However, embodiments of the present disclosure are not necessarily limited thereto.

As described below, in an embodiment the 2nd-1 bridge contact layer BCLS2 and the 2nd-2 bridge contact layer BCLD2 may be simultaneously formed using the same material while the 1st-1 bridge contact layer BCLS1 and the 1st-2 bridge contact layer BCLD1 are formed. However, unlike the 1st-1 bridge contact layer BCLS1 and the 1st-2 bridge contact layer BCLD1, each of the 2nd-1 bridge contact layer BCLS2 and the 2nd-2 bridge contact layer BCLD2 is not in direct contact with the second semiconductor layer A2. Accordingly, in amorphous silicon doped with impurities of the 2nd-1 bridge contact layer BCLS2 and the 2nd-2 bridge contact layer BCLD2, performance deterioration of the second semiconductor layer A2 due to diffusion of the impurities into the second semiconductor layer A2 may be prevented.

Up to this point, although description has been made to the display apparatus 1, embodiments of the present disclosure are not necessarily limited thereto. A method of manufacturing the display apparatus 1 also falls within the scope of the disclosure. Hereinafter, the method of manufacturing the display apparatus 1 is described.

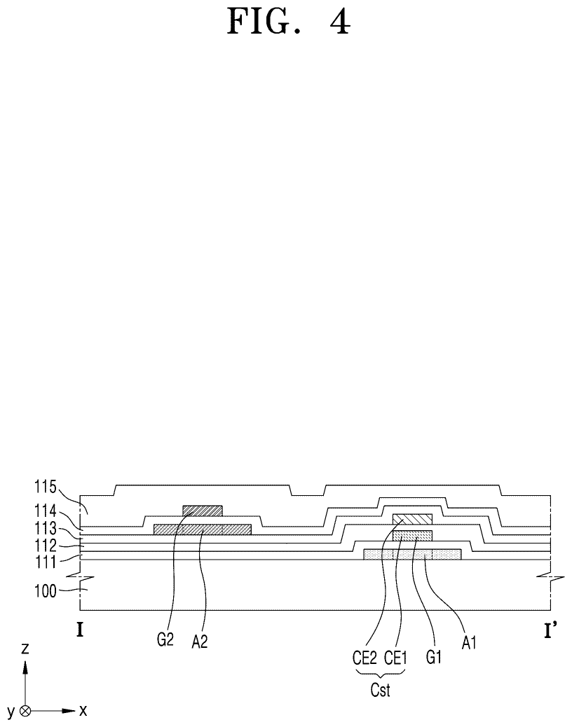

FIGS. 4 to 9 are schematic cross-sectional views showing some of a process of manufacturing the display apparatus 1 of FIG. 3. Specifically, FIGS. 4 to 9 are schematic cross-sectional views of processes of manufacturing the 1st-1 connection electrode S1, the 1st-2 connection electrode D1, the 2nd-1 connection electrode S2, the 2nd-2 connection electrode D2, the 1st-1 bridge contact layer BCLS1, the 1st-2 bridge contact layer BCLD1, the 2nd-1 bridge contact layer BCLS2, and the 2nd-2 bridge contact layer BCLD2 of the display apparatus 1 of FIG. 3. For convenience of description, FIGS. 4 to 9 describes the method of manufacturing the display apparatus based on a cross-section of the display apparatus 1, taken along line I-I′ of the display apparatus 1. Hereinafter, in describing the method of manufacturing the display apparatus according to embodiments with reference to FIGS. 4 to 9, since same reference numerals as those in FIGS. 1 to 3 denote the same members, repeated descriptions thereof may be omitted for economy of description.

As shown in FIG. 4, in an embodiment the first inorganic insulating layer 111, the second inorganic insulating layer 112, the third inorganic insulating layer 113, the fourth inorganic insulating layer 114, and the fifth inorganic insulating layer 115 may be formed over the substrate 100. The first inorganic insulating layer 111 is formed to be disposed between the first semiconductor layer A1 and the first gate electrode G1, and the second inorganic insulating layer 112 may be formed to be disposed between the first gate electrode G1 and the second capacitor electrode CE2 (e.g., in the Z-axis direction). The third inorganic insulating layer 113 is formed on (e.g., formed directly thereon) the second capacitor electrode CE2, and the fourth inorganic insulating layer 114 is formed to be disposed between the second semiconductor layer A2 and the second gate electrode G2. The fifth inorganic insulating layer 115 may be formed on (e.g., formed directly thereon) the second gate electrode G2.

The first semiconductor layer A1 and the first gate electrode G1 of the silicon thin-film transistor S-TFT, the storage capacitor Cst, and the second semiconductor layer A2 and the second gate electrode G2 of the oxide thin-film transistor O-TFT may be disposed on the substrate 100. For example, the first semiconductor layer A1 may be formed on the substrate 100, the first inorganic insulating layer 111 may be formed on the first semiconductor layer A1, and the first gate electrode G1 may be formed on the first inorganic insulating layer 111. In an embodiment, the first gate electrode G1 may serve as the first capacitor electrode CE1 of the storage capacitor Cst. In an embodiment, the second inorganic insulating layer 112 may then be formed on the first gate electrode G1, and the second capacitor electrode CE2 may be formed on the second inorganic insulating layer 112, and the third inorganic insulating layer 113 may be formed on the second capacitor electrode CE2. In an embodiment, the second semiconductor layer A2 may then be formed on the third inorganic insulating layer 113, the fourth inorganic insulating layer 114 may be formed on the second semiconductor layer A2, and the second gate electrode G2 may be formed on the fourth inorganic insulating layer 114. In an embodiment, the fifth inorganic insulating layer 115 may be formed on the second gate electrode G2. For example, the first inorganic insulating layer 111, the second inorganic insulating layer 112, the third inorganic insulating layer 113, the fourth inorganic insulating layer 114, and the fifth inorganic insulating layer 115 may be formed over the substrate 100.

Thus, a portion of the pixel circuit PC described above with reference to FIG. 3 is formed on the substrate 100. For example, the first semiconductor layer A1 and the first gate electrode G1 of the silicon thin-film transistor S-TFT are formed on the substrate 100, the first capacitor electrode CE1 and the second capacitor electrode CE2 of the storage capacitor Cst are formed on the substrate 100, and the second semiconductor layer A2 and the second gate electrode of the oxide thin-film transistor O-TFT are formed on the substrate 100. The first inorganic insulating layer 111 is formed to be disposed between the first semiconductor layer A1 and the first gate electrode G1, and the second inorganic insulating layer 112 may be formed to be disposed between the first gate electrode G1 and the second capacitor electrode CE2. The third inorganic insulating layer 113 is formed on the second capacitor electrode CE2, and the fourth inorganic insulating layer 114 is formed to be disposed between the second semiconductor layer A2 and the second gate electrode G2. The fifth inorganic insulating layer 115 may be formed on the second gate electrode G2.

In an embodiment, the fifth inorganic insulating layer 115 may be formed on the second gate electrode G2 and formed over the substrate 100 entirely. Accordingly, as shown in FIG. 4, the fifth inorganic insulating layer 115 may cover the first semiconductor layer A1 of the silicon thin-film transistor S-TFT and the second semiconductor layer A2 of the oxide thin-film transistor O-TFT. For example, the fifth inorganic insulating layer 115 may be disposed on the first semiconductor layer A1 of the silicon thin-film transistor S-TFT and the second semiconductor layer A2 of the oxide thin-film transistor O-TFT. As described above, in an embodiment each of the first inorganic insulating layer 111, the second inorganic insulating layer 112, the third inorganic insulating layer 113, the fourth inorganic insulating layer 114, and the fifth inorganic insulating layer 115 may include an inorganic material such as silicon oxide (SiO_{X}), silicon nitride (SiN_{X}), and/or silicon oxynitride (SiO_{X}N_{Y}), and have a single layer or a multi-layered structure including the above materials. In an embodiment, the first inorganic insulating layer 111, the second inorganic insulating layer 112, the third inorganic insulating layer 113, the fourth inorganic insulating layer 114, and the fifth inorganic insulating layer 115 each including the inorganic material may be formed using the CVD or atomic layer deposition (ALD).

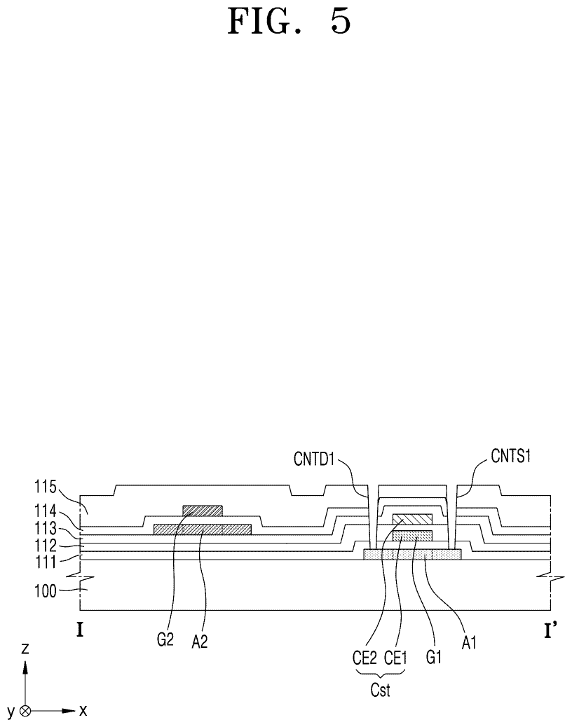

In an embodiment, as shown in FIG. 5, the 1st-1 contact hole CNTS1 and the 1st-2 contact hole CNTD1 passing through (e.g., in the Z-axis direction) the first inorganic insulating layer 111, the second inorganic insulating layer 112, the third inorganic insulating layer 113, the fourth inorganic insulating layer 114, and the fifth inorganic insulating layer 115 may then be formed. For example, a portion of the fifth inorganic insulating layer 115 may be removed entirely in the thickness direction (e.g., +z direction or −z direction) from the upper surface of the fifth inorganic insulating layer 115, and a portion of the fourth inorganic insulating layer 114 may be removed entirely in the thickness direction (e.g., +z direction or −z direction) from the upper surface of the fourth inorganic insulating layer 114. Together, a portion of the third inorganic insulating layer 113 may be removed entirely in the thickness direction (e.g., +z direction or −z direction) from the upper surface of the third inorganic insulating layer 113, a portion of the second inorganic insulating layer 112 may be removed entirely in the thickness direction (e.g., +z direction or −z direction) from the upper surface of the second inorganic insulating layer 112, and a portion of the first inorganic insulating layer 111 may be removed entirely in the thickness direction (e.g., +z direction or −z direction) from the upper surface of the first inorganic insulating layer 111. In an embodiment, a photolithography process using a mask and an etching process may be used to form the contact holes. However, embodiments of the present disclosure are not necessarily limited thereto, and any process commonly used to form contact holes in inorganic insulating layers can be used.

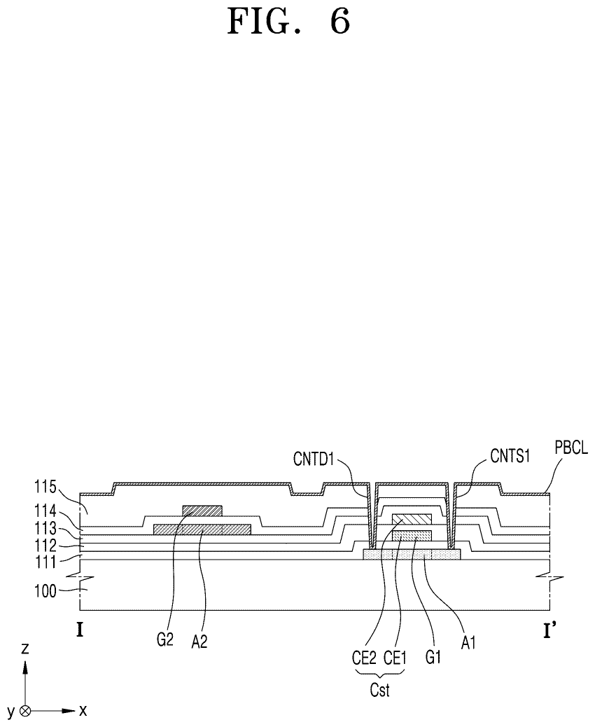

In an embodiment, as shown in FIG. 6, a first preliminary bridge contact layer PBCL may then be formed on the fifth inorganic insulating layer 115. For example, the first preliminary bridge contact layer PBCL may be formed on (e.g., formed directly thereon) the fifth inorganic insulating layer 115 to correspond to (e.g., overlap in the Z-axis direction) an entire surface of the substrate 100. As an example, in an embodiment the first preliminary bridge contact layer PBCL may be formed on the entire surface of the substrate 100 using the CVD inside a chamber. Accordingly, the first preliminary bridge contact layer PBCL may cover the inner surface of the 1st-1 contact hole CNTS1 and the inner surface of the 1st-2 contact hole CNTD1. The first preliminary bridge contact layer PBCL may cover a portion of the upper surface of the first semiconductor layer A1 corresponding to the 1st-1 contact hole CNTS1 and a portion of the upper surface of the first semiconductor layer A1 corresponding to the 1st-2 contact hole CNTD1.

In an embodiment, the first preliminary bridge contact layer PBCL may include amorphous silicon doped with impurities, and the impurities may include N-type impurities or P-type impurities. As an example, the first preliminary bridge contact layer PBCL may include p-type amorphous silicon doped with impurities such as boron (B), aluminum (Al), or indium (In). Alternatively, the first preliminary bridge contact layer PBCL may include n-type amorphous silicon doped with impurities such as phosphorus (P), arsenic (As), or antimony (Sb). In an embodiment, the first preliminary bridge contact layer PBCL may include a metal material. As an example, the first preliminary bridge contact layer PBCL may include tungsten (W). In another embodiment, the first preliminary bridge contact layer PBCL may include conductive metal nitride. As an example, the first preliminary bridge contact layer PBCL may include titanium nitride (TiN). However, embodiments of the present disclosure are not necessarily limited thereto.

Like an embodiment in which the first preliminary bridge contact layer PBCL includes amorphous silicon doped with impurities, the first preliminary bridge contact layer PBCL including tungsten (W) or titanium nitride (TiN) may be also formed using the CVD. Since a method using the CVD is common in the formation of a layer including tungsten (W) or titanium nitride (TiN), detailed description is omitted for economy of description.

As described above, the sputtering method has a higher anisotropy than the CVD. Accordingly, in the case of filling a contact hole having a relatively long shape in a thickness direction (e.g., +z direction or −z direction) with a layer including a conductive material using the sputtering method, a portion of the inner surface of the contact hole may not be covered by the layer including the conductive material. The 1st-1 contact hole CNTS1 and the 1st-2 contact hole CNTD1 have a relatively long shape in the thickness direction (e.g., +z direction or −z direction). However, in an embodiment of the present disclosure, the first preliminary bridge contact layer PBCL is formed using the CVD method. Accordingly, since the first preliminary bridge contact layer PBCL has an excellent step coverage, the first preliminary bridge contact layer PBCL may cover the entire inner surface of the 1st-1 contact hole CNTS1 of the entire inner surface of the 1st-2 contact hole CNTD1.

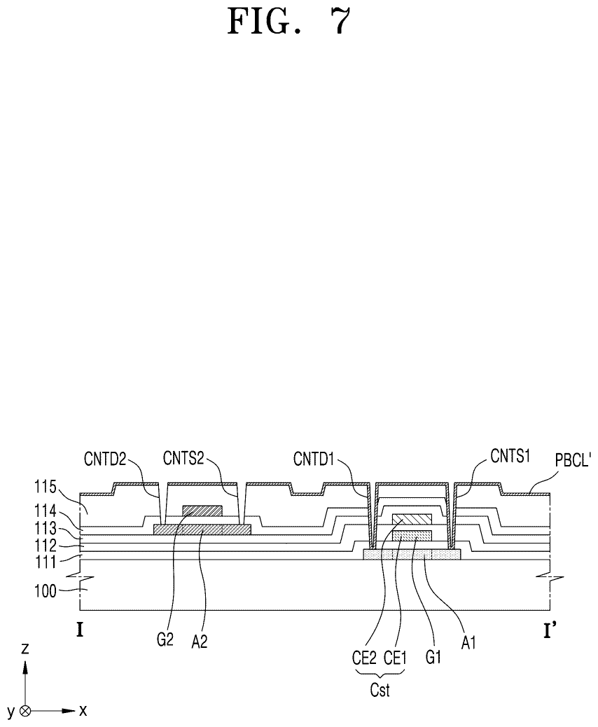

In an embodiment, as shown in FIG. 7, the 2nd-1 contact hole CNTS2 and the 2nd-2 contact hole CNTD2 passing through the fourth inorganic insulating layer 114 and the fifth inorganic insulating layer 115 may then be formed. Accordingly, a second preliminary bridge contact layer PBCL′ may be formed. For example, a portion of the fifth inorganic insulating layer 115 may be removed entirely in the thickness direction (e.g., +z direction or −z direction) from the upper surface of the fifth inorganic insulating layer 115, and a portion of the fourth inorganic insulating layer 114 may be removed entirely in the thickness direction (e.g., +z direction or −z direction) from the upper surface of the fourth inorganic insulating layer 114. Together, a portion of the first preliminary bridge contact layer PBCL corresponding to a portion of the fifth inorganic insulating layer 115 may be also removed. For example, a portion of the first preliminary bridge contact layer PBCL disposed on a portion of the fifth inorganic insulating layer 115 may be also removed together. For example, the second preliminary bridge contact layer PBCL′ may be the first preliminary bridge contact layer PBCL in which portions corresponding to the 2nd-1 contact hole CNTS2 and the 2nd-2 contact hole CNTD2 have been removed. In an embodiment, a photolithography process and an etching process may be used to form the contact holes. However, embodiments of the present disclosure are not necessarily limited thereto, and any process commonly used to form contact holes in inorganic insulating layers can be used.

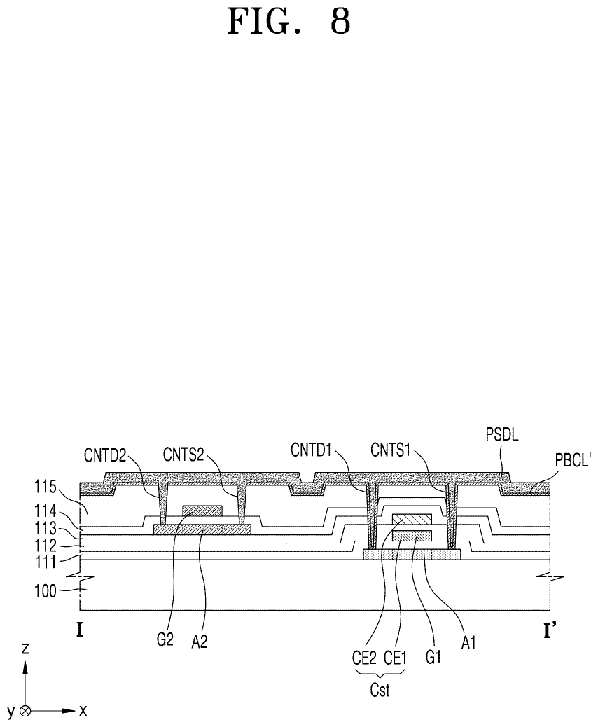

In an embodiment, as shown in FIG. 8, a preliminary connection electrode layer PSDL may then be formed on the second preliminary bridge contact layer PBCL′. For example, the preliminary connection electrode layer PSDL may be formed on the second preliminary bridge contact layer PBCL′ to correspond to the entire surface of the substrate 100. As an example, the preliminary connection electrode layer PSDL may be formed on the entire surface of the substrate 100 using the sputtering method inside the chamber. Accordingly, the preliminary connection electrode layer PSDL may cover the inner surface of the 2nd-1 contact hole CNTS2 and the inner surface of the 2nd-2 contact hole CNTD2. The preliminary connection electrode layer PSDL may also cover a portion of the second semiconductor layer A2 corresponding to the 2nd-1 contact hole CNTS2 and a portion of the second semiconductor layer A2 corresponding to the 2nd-2 contact hole CNTD2. In addition, the preliminary connection electrode layer PSDL may also cover a portion of the second preliminary bridge contact layer PBCL′ covering the inner surface of the 1st-1 contact hole CNTS1 and a portion of the second preliminary bridge contact layer PBCL′ covering the inner surface of the 1st-2 contact hole CNTD1. The preliminary connection electrode layer PSDL may also cover a portion of the second preliminary bridge contact layer PBCL′ covering a portion of the first semiconductor layer A1. In an embodiment, the preliminary connection electrode layer PSDL may include a conductive material including molybdenum (Mo), aluminum (Al), copper (Cu), titanium (Ti), or the like. However, embodiments of the present disclosure are not necessarily limited thereto.

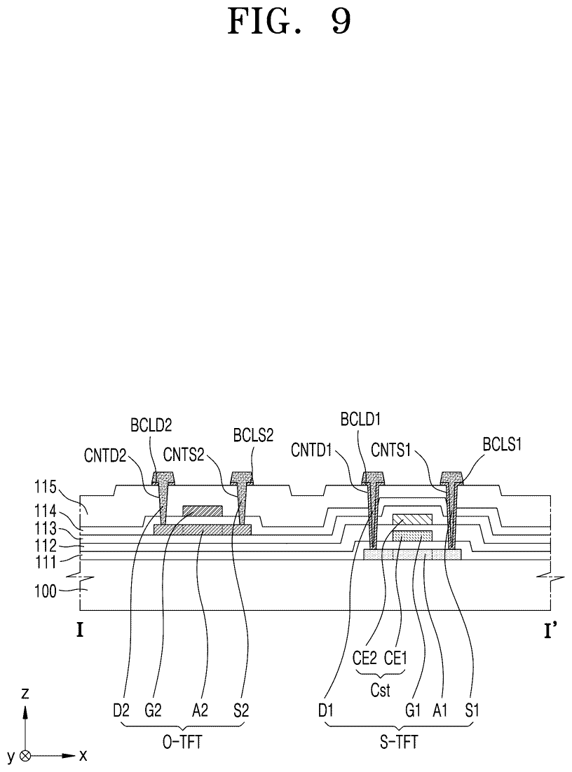

In an embodiment, as shown in FIG. 9, by patterning the preliminary connection electrode layer PSDL and the second preliminary bridge contact layer PBCL′, the 1st-1 connection electrode S1, the 1st-2 connection electrode D1, the 2nd-1 connection electrode S2, the 2nd-2 connection electrode D2, the 1st-1 bridge contact layer BCLS1, the 1st-2 bridge contact layer BCLD1, the 2nd-1 bridge contact layer BCLS2 and the 2nd-2 bridge contact layer BCLD2 may be formed. In an embodiment, a photolithography process using a mask and an etching process may be used in patterning. However, embodiments of the present disclosure are not necessarily limited to thereto, and any process commonly used for patterning may be used.

According to an embodiment, the display apparatus with a reduced defect occurrence possibility during a manufacturing process may be implemented. However, the scope of embodiments of the present disclosure are not necessarily limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus comprising:
a first semiconductor layer disposed on a substrate;
a first gate electrode disposed over the first semiconductor layer;
a first inorganic insulating layer disposed between the first semiconductor layer and the first gate electrode;
a capacitor electrode disposed over the first gate electrode to overlap the first gate electrode;
a second inorganic insulating layer disposed between the first gate electrode and the capacitor electrode;
a third inorganic insulating layer disposed on the capacitor electrode;
a second semiconductor layer disposed on the third inorganic insulating layer;
a second gate electrode disposed over the second semiconductor layer;
a fourth inorganic insulating layer disposed between the second semiconductor layer and the second gate electrode;
a fifth inorganic insulating layer disposed on the second gate electrode;
a 1st-1 connection electrode disposed over the fifth inorganic insulating layer, the 1st-1 connection electrode is electrically connected to the first semiconductor layer through a 1st-1 contact hole passing through the first inorganic insulating layer, the second inorganic insulating layer, the third inorganic insulating layer, the fourth inorganic insulating layer, and the fifth inorganic insulating layer; and
a 1st-1 bridge contact layer covering a portion of the fifth inorganic insulating layer, an inner surface of the 1st-1 contact hole, and a portion of the first semiconductor layer corresponding to the 1st-1 contact hole.

2. The display apparatus of claim 1, wherein the 1st-1 bridge contact layer directly contacts the portion of the first semiconductor layer corresponding to the 1st-1 contact hole.

3. The display apparatus of claim 2, wherein the 1st-1 connection electrode directly contacts the 1st-1 bridge contact layer.

4. The display apparatus of claim 3, wherein the 1st-1 bridge contact layer conformally covers the 1st-1 connection electrode.

5. The display apparatus of claim 3, wherein the 1st-1 bridge contact layer has a shape corresponding to a lower surface of the 1st-1 connection electrode.

6. The display apparatus of claim 1, wherein the first semiconductor layer includes a silicon semiconductor.

7. The display apparatus of claim 1, wherein the second semiconductor layer includes an oxide semiconductor.

8. The display apparatus of claim 1, wherein the 1st-1 bridge contact layer includes amorphous silicon doped with N-type impurities or P-type impurities.

9. The display apparatus of claim 1, wherein the 1st-1 bridge contact layer includes tungsten or titanium nitride.

10. The display apparatus of claim 1, further comprising:
a 2nd-1 connection electrode disposed over the fifth inorganic insulating layer, the 2nd-1 connection electrode is electrically connected to the second semiconductor layer through a 2nd-1 contact hole passing through the fourth inorganic insulating layer and the fifth inorganic insulating layer; and
a 2nd-1 bridge contact layer covering a portion of the fifth inorganic insulating layer, the 2nd-1 bridge contact layer is spaced apart from the second semiconductor layer.

11. The display apparatus of claim 10, wherein the 2nd-1 connection electrode directly contacts the second semiconductor layer.

12. The display apparatus of claim 10, wherein the 2nd-1 bridge contact layer does not directly contact an inner surface of the 2nd-1 contact hole and a portion of the second semiconductor layer corresponding to the 2nd-1 contact hole.

13. The display apparatus of claim 10, wherein the 2nd-1 bridge contact layer includes a same material as the 1st-1 bridge contact layer.

14. A method of manufacturing a display apparatus, the method comprising:
forming a first inorganic insulating layer, a second inorganic insulating layer, a third inorganic insulating layer, a fourth inorganic insulating layer, and a fifth inorganic insulating layer over a substrate;
forming a 1st-1 contact hole passing through the first inorganic insulating layer, the second inorganic insulating layer, the third inorganic insulating layer, the fourth inorganic insulating layer, and the fifth inorganic insulating layer;
forming a first preliminary bridge contact layer on the fifth inorganic insulating layer;
forming a second preliminary bridge contact layer by forming a 2nd-1 contact hole passing through the fourth inorganic insulating layer and the fifth inorganic insulating layer, and removing a portion of the first preliminary bridge contact layer corresponding to the 2nd-1 contact hole;
forming a preliminary connection electrode on the second preliminary bridge contact layer; and
forming a 1st-1 connection electrode, a 2nd-1 connection electrode, a 1st-1 bridge contact layer, and a 2nd-1 bridge contact layer by patterning the preliminary connection electrode layer and the second preliminary bridge contact layer.

15. The method of claim 14, wherein the forming of the first preliminary bridge contact layer includes forming the first preliminary bridge contact layer using chemical vapor deposition.

16. The method of claim 14, wherein the first preliminary bridge contact layer includes amorphous silicon doped with N-type impurities or P-type impurities.

17. The method of claim 14, wherein the first preliminary bridge contact layer includes tungsten or titanium nitride.

18. The method of claim 14, wherein the forming of the first preliminary bridge contact layer includes covering an inner surface of the 1st-1 contact hole with the first preliminary bridge contact layer.

19. The method of claim 14, wherein the forming of the first inorganic insulating layer, the second inorganic insulating layer, the third inorganic insulating layer, the fourth inorganic insulating layer, and the fifth inorganic insulating layer over the substrate includes:
forming the first inorganic insulating layer to be disposed between a first semiconductor layer and a first gate electrode;
forming the second inorganic insulating layer to be disposed between the first gate electrode and a capacitor electrode;
forming the third inorganic insulating layer on the capacitor electrode;
forming the fourth inorganic insulating layer to be disposed between a second semiconductor layer and a second gate electrode; and
forming the fifth inorganic insulating layer on the second gate electrode.

20. The method of claim 19, wherein:
the 1st-1 connection electrode is electrically connected to the first semiconductor layer through the 1st-1 contact hole; and
the 2nd-1 connection electrode is electrically connected to the second semiconductor layer through the 2nd-1 contact hole.
